(19) United States
(12) Patent Application Publication
(10) Pub. No.: US 2025/0287640 A1
(43) Pub. Date: Sep. 11, 2025

(54) POWER SEMICONDUCTOR DEVICES

(71) Applicant: Samsung Electronics Co., Ltd., Suwon-si (KR)

(72) Inventors: Taehun Kim, Suwon-si (KR); Doohyung Cho, Suwon-si (KR); Mingu Ko, Suwon-si (KR); Youngcheol Kim, Suwon-si (KR); Jongseob Kim, Suwon-si (KR); Gyeongseon Park, Suwon-si (KR)

(73) Assignee: Samsung Electronics Co., Ltd., Suwon-si (KR)

(21) Appl. No.: 18/909,723

(22) Filed: Oct. 8, 2024

(30) Foreign Application Priority Data
Mar. 8, 2024 (KR) 10-2024-0033127

(51) Int. Cl. H01L 29/78; H01L 29/06; H01L 29/417

(52) U.S. Cl. CPC H10D 30/665; H10D 62/102; H10D 64/252

(57) ABSTRACT

A power semiconductor device includes a substrate including a cell region and an edge region extending from the cell region, a drift layer of a first conductivity type on the substrate, a first well region of a second conductivity type disposed within the drift layer, a source region of the first conductivity type disposed within the first well region, an insulating liner on the drift layer, gate electrodes spaced apart from each other on the insulating liner, an insulating pattern in the edge region, a conductive pattern spaced apart from the gate electrodes and covering a portion of the insulating liner and further covering a portion of the insulating pattern, a dielectric layer covering the gate electrodes and the conductive pattern, a source electrode on the dielectric layer, and a source contact plug penetrating through the dielectric layer and connecting the source electrode and the source region.

### RELATED APPLICATION(S)

This application claims the benefit under 35 USC 119(a) of Korean Patent Application No. 10-2024-0033127 filed on Mar. 8, 2024 in the Korean Intellectual Property Office, the entire disclosure of which is incorporated herein by reference for all purposes.

### FIELD

The present disclosure relate to power semiconductor devices, and to Metal Oxide Semiconductor Field Effect Transistor (MOSFET) power semiconductor devices.

### BACKGROUND

Power semiconductor devices are semiconductor devices that operate in high voltage and high current environments and are used in fields requiring high power switching, such as power conversion, power converters, inverters, and the like. Power semiconductor devices are typically required to withstand high voltages, and now they are additionally required to perform high-speed switching operations. Accordingly, research into power semiconductor devices using Silicon Carbide (SiC), which has superior high voltage tolerance compared to silicon (Si), is being undertaken.

### SUMMARY

Example embodiments provide a power semiconductor device having improved reliability by significantly reducing a step difference between a cell region and an edge region extending from the cell region.

According to example embodiments, a power semiconductor device includes a substrate including a cell region and an edge region extending from the cell region; a drift layer of a first conductivity type on the substrate; a first well region of a second conductivity type extending from an upper surface of the drift layer in the cell region and disposed within the drift layer; a source region of the first conductivity type extending from an upper surface of the first well region and disposed within the first well region; an insulating liner on the drift layer; gate electrodes spaced apart from each other on the insulating liner in the cell region, with the source region interposed therebetween; an insulating pattern in the edge region; a conductive pattern spaced apart from the gate electrodes and covering a portion of the insulating liner and a portion of the insulating pattern; a dielectric layer covering the gate electrodes and the conductive pattern; a source electrode on the dielectric layer; and a source contact plug penetrating through the dielectric layer and connecting the source electrode and the source region. The conductive pattern includes a first pattern in contact with the insulating liner and a second pattern in contact with the insulating pattern, and an upper surface of the first pattern is disposed on the same level as an upper surface of the second pattern.

According to example embodiments, a power semiconductor device includes a substrate including a first region and a second region surrounding the first region; a drift layer of a first conductivity type on the substrate; a first well region of a second conductivity type extending from an upper surface of the drift layer on the first region and disposed within the drift layer; a source region of the first conductivity type extending from an upper surface of the first well region and disposed within the first well region; an insulating liner on the drift layer; an insulating pattern on the second region; gate electrodes on the insulating liner on the first region and spaced apart from each other in a first direction with the source region interposed therebetween; a conductive pattern spaced apart from the gate electrodes and covering a portion of the insulating liner and a portion of the insulating pattern; a dielectric layer covering the gate electrodes and the conductive pattern; and a source electrode on the dielectric layer in the first region. The conductive pattern includes a first pattern disposed on the insulating liner and a second pattern extending from the first pattern and disposed on the insulating pattern. The first pattern has a first height in a vertical direction intersecting the first direction from an upper surface of the insulating liner, and the second pattern has a second height, lower than the first height, in the vertical direction, from an upper surface of the insulating pattern.

According to example embodiments, a power semiconductor device includes a substrate of a first conductivity type; a drift layer of a first conductivity type on the substrate; a first well region of a second conductivity type on the drift layer; a second well region of the second conductivity type disposed on the drift layer and spaced apart from the first well region in a first direction; source regions of the first conductivity type on the first well region; an insulating liner on the drift layer; gate electrodes spaced apart from each other, with the source region interposed therebetween, on the first well region; an insulating pattern disposed on a portion of the insulating liner, on the second well region; a conductive pattern spaced apart from the gate electrodes and covering a portion of the insulating liner and a portion of the insulating pattern on the second well region; a dielectric layer covering the gate electrodes and the conductive pattern; a source electrode on the dielectric layer; and a source contact plug penetrating through the dielectric layer and connecting the source electrode and the source region. The conductive pattern includes a first pattern in contact with the insulating liner and a second pattern in contact with the insulating pattern, and an upper surface of the first pattern and an upper surface of the second pattern are disposed on the same level. An upper surface of the dielectric layer is disposed on the same level as an upper surface of the source contact plug.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a schematic plan view of a power semiconductor device according to example embodiments;

FIG. 2A is a cross-sectional view illustrating an example embodiment of the power semiconductor device of FIG. 1, taken along line I-I′;

FIG. 2B is an enlarged view of region A of the power semiconductor device of FIG. 2A;

FIG. 3A is a cross-sectional view illustrating another embodiment of the power semiconductor device of FIG. 1, taken along line I-I′;

FIG. 3B is an enlarged view of region B of the power semiconductor device of FIG. 3A;

FIGS. 4A to 4E are cross-sectional views illustrating another embodiment of the power semiconductor device of FIG. 1, taken along line I-I′; and

FIGS. 5A to 5F are diagrams illustrating an example embodiment of a method of manufacturing the power semiconductor device of FIG. 2A.

### DETAILED DESCRIPTION

Hereinafter, example embodiments of the present disclosure will be described in more detail with reference to the attached drawings. The same reference numerals are used for the same components in the drawings, and duplicate descriptions of the same components are omitted.

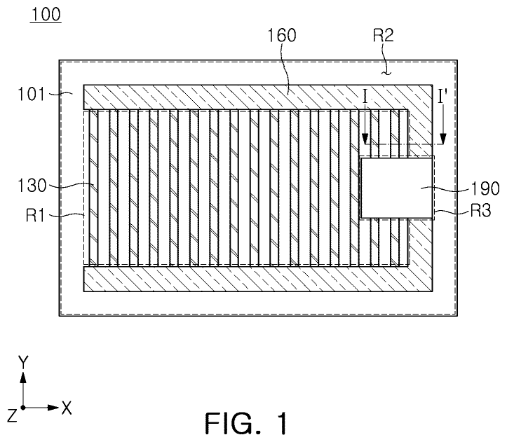

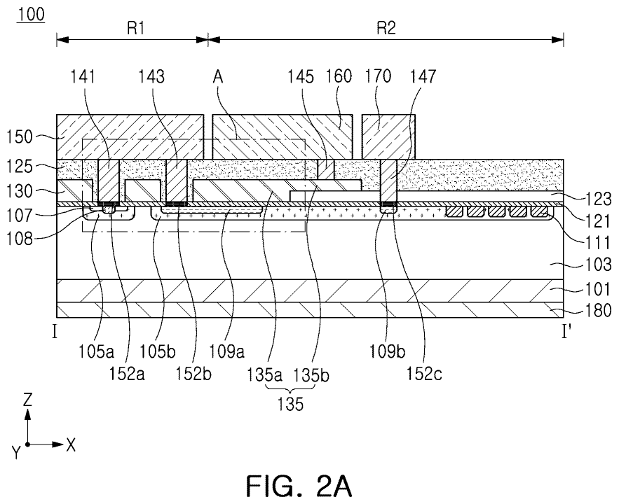

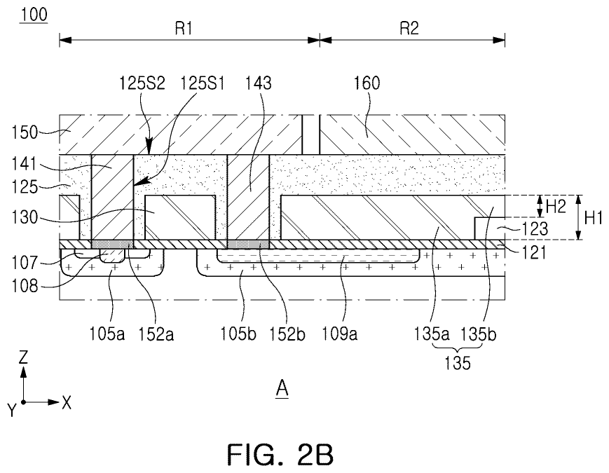

FIG. 1 is a schematic plan view of a power semiconductor device according to example embodiments. FIG. 2A is a cross-sectional view illustrating an example embodiment of the power semiconductor device of FIG. 1, taken along line I-I′. FIG. 2B is an enlarged view of region A of the power semiconductor device of FIG. 2A.

Referring to FIGS. 1 and 2A, a power semiconductor device 100 may include a substrate 101, a drift layer 103 on the substrate 101, first and second well regions 105a and 105b extending from the upper surface of the drift layer 103 and spaced apart from each other, source regions 107 disposed on the first well region 105a, a well contact region 108 disposed on one side of the source regions 107, peripheral contact regions 109a and 109b disposed on the second well region 105b, an insulating liner 121 disposed on the drift layer 103, gate electrodes 130 on insulating liner 121, a conductive pattern 135 spaced apart from the gate electrodes 130, a dielectric layer 125 covering the gate electrodes 130 and the conductive pattern 135, a source electrode 150 and a gate bus line 160 on the dielectric layer 125, a source contact plug 141 penetrating through the dielectric layer 125 and connecting to the source regions 107 and the source electrode 150, and a drain electrode 180 on the lower surface of the substrate 101.

The substrate 101 may have an upper surface extending in a first direction (X-direction) and a second direction (Y-direction). The substrate 101 may include a semiconductor material, for example, SiC. However, in some embodiments, the substrate 101 may include a group IV semiconductor material such as Si or Ge, or a compound semiconductor material such as SiGe, GaAs, InAs, or InP.

The substrate 101 may be provided as a bulk wafer or an epitaxial layer. The substrate 101 may include first conductivity type impurities and thus may have a first conductivity type. In some embodiments, the first conductivity type may be, for example, N-type, and the first conductivity type impurities may be N-type impurities, for example, nitrogen (N) and/or phosphorus (P). In some embodiments, the first conductivity type may be, for example, P-type, and the first conductivity type impurities may be, for example, P-type impurities such as aluminum (Al).

The substrate 101 may include a first region R1 where gate electrodes 130 are disposed, a second region R2 surrounding at least one side of the first region R1 and in which gate bus lines 160 are disposed, and a third region R3 where the gate pad 190 electrically connected to the gate electrodes 130 is disposed. In this document, the first region R1 may be referred to as a cell region, and the second region R2 may be referred to as an edge region. The third region R3 may be referred to as a gate pad region.

The drift layer 103 may be disposed on the substrate 101. The drift layer 103 may include a semiconductor material. For example, the semiconductor material may include SiC. The drift layer 103 may be an epitaxial layer grown on the substrate 101. The drift layer 103 may include impurities of a first conductivity type and thus may have the first conductivity type. The concentration of first conductivity type impurities in the drift layer 103 may be lower than the concentration of first conductivity type impurities in the substrate 101. In example embodiments, the first conductivity type impurities in the substrate 101 and the drift layer 104 may be the same or different from each other.

The first and second well regions 105a and 105b may be disposed at a predetermined depth from the upper surface of the drift layer 103. The first and second well regions 105a and 105b may be disposed to be spaced apart from each other in the horizontal direction. The first and second well regions 105a and 105b may include a semiconductor material, for example, SiC. The first and second well regions 105a and 105b may be regions having a second conductivity type and may include impurities of the second conductivity type. For example, the second conductivity type may be P-type, and the second conductivity type impurities may be P-type impurities such as aluminum (Al) or boron (B).

The first well region 105a may overlap the first region R1 of the substrate 101 in the vertical direction (Z-direction). The second well region 105b may be spaced apart from the first well region 105a in the first direction (X-direction) and may be disposed to surround at least one side of the first well region 105a. In an example, the second well region 105b may extend from the first region R1 to the second region R2. The second well region 105b is illustrated as being disposed across the first and second regions R1 and R2, but is not limited thereto. For example, the second well region 105b may not overlap the first region R1 in the vertical direction (Z-direction), but may overlap the second region R2 in the vertical direction (Z-direction).

The first and second well regions 105a and 105b may have substantially the same thickness in the vertical direction (Z-direction). However, the present disclosure is not limited thereto, and the thickness of the first well region 105a in the vertical direction (Z-direction) may be smaller or larger than the thickness of the second well region 105b.

The source regions 107 may each be disposed in the first well region 105a and may be disposed at a predetermined depth from the upper surface of the first well region 105a. The thickness of the source region 107 in the vertical direction (Z-direction) may be smaller than the thickness of the first well region 105a. Source region 107 may include a semiconductor material, for example, SiC. The source region 107 may be a region having a first conductivity type and may include the first conductivity type impurities described above. The concentration of impurities of the first conductivity type in the source region 107 may be higher than the concentration of impurities of the first conductivity type in the drift layer 103, but is not limited thereto.

The power semiconductor device 100 according to example embodiments may further include a well contact region 108 disposed on one side of the source regions 107. The well contact region 108 may be disposed at a predetermined depth from the upper surface of the drift layer 103. In an example, the well contact region 108 may extend from the upper surface of the drift layer 103 and be disposed within the first well region 105a. The well contact region 108 may be disposed and/or formed across the source region 107 in the vertical direction (Z-direction). In an example, the well contact region 108 may be disposed between the source regions 107 within the first well region 105a to apply the voltage from the source electrode 150 to the first well region 105a. The well contact region 108 may include a semiconductor material, for example, SiC. The well contact region 108 may be a region having the second conductivity type, and may include the second conductivity type impurities described above. The concentration of the second conductivity type impurities in the well contact region 108 may be higher than the concentration of the second conductivity type impurities in the first well region 105a.

The peripheral contact regions 109a and 109b may extend from the upper surface of the drift layer 103 and be disposed within the second well region 105b. The peripheral contact regions 109a and 109b may be spaced apart from the well contact region 108 in a horizontal direction (for example, first and second directions (X- and Y-directions)). In an example, the peripheral contact regions 109a and 109b may include a first peripheral contact region 109a and a second peripheral contact region 109b spaced apart from the first peripheral contact region 109a. The first peripheral contact region 109a may be disposed to extend from within the second well region 105b disposed in the first region R1 to the second region R2. The concentration of second conductivity type impurities in the peripheral contact regions 109a and 109b may be higher than the concentration of second conductivity type impurities in the second well region 105b. In an example, the peripheral contact regions 109a, 109b may be surface depletion protection regions to prevent depletion in the region at or near the upper surface of the drift layer 103 disposed on the second region R2.

The first and second peripheral contact regions 109a and 109b may include a semiconductor material, for example, SiC. The first and second peripheral contact regions 109a and 109b may be regions having the second conductivity type and may include the above-described second conductivity type impurities. The concentration of second conductivity type impurities in the first and second peripheral contact regions 109a and 109b may be higher than the concentration of second conductivity type impurities in the second well region 105b.

The power semiconductor device 100 according to example embodiments may further include at least one guard ring 111 disposed in the second well region 105b disposed in the second region R2. The at least one guard ring 111 is disposed to be spaced apart from the conductive pattern 135, and may be disposed to surround the first region R1 in the area closest to the edge of the substrate 101 within the second region R2. At least one guard ring 111 may be a region having a second conductivity type and may include second conductivity type impurities. The concentration of impurities of the second conductivity type in the at least one guard ring 111 may be higher than the concentration of impurities of the second conductivity type in the second well region 105b. The drawing illustrates five guard rings 111, but is not limited thereto.

The gate electrodes 130 may be disposed on the first region R1 of the substrate 101. The gate electrodes 130 may extend in the second direction (Y-direction) on the first region R1 and be spaced apart from each other in the first direction (X-direction). The gate electrodes 130 may be disposed on the insulating liner 121 disposed on the first region R1 of the substrate 101. The gate electrode 130 may overlap one end of the source regions 107 and the first well region 105a outside the source regions 107 in the vertical direction (Z-direction). The gate electrodes 130 may be spaced apart from the source region 107, the first well region 105a, and the drift layer 103 by the insulating liner 121.

When viewed in plan view, the gate electrodes 130 are illustrated as not overlapping with the gate bus lines 160 and the gate pad 190, but some of the gate electrodes 130 may be disposed to overlap the gate bus lines 160 and the gate pad 190 in the vertical direction (Z-direction).

The gate electrode 130 may include a conductive material, for example, semiconductor materials such as doped polycrystalline silicon, metal nitride, such as titanium nitride (TiN), tantalum nitride (TaN), or tungsten nitride (WN), and/or metallic substances such as aluminum (Al), tungsten (W), or molybdenum (Mo). Depending on example embodiments, the gate electrode 130 may be composed of two or more layers.

The insulating liner 121 may be disposed on the upper surface of the drift layer 103. The insulating liner 121 may extend onto the source region 107, the first well region 105a outside of the source region 107, the drift layer 103, and the second well region 105b. In an example, the insulating liner 121 may function as a gate insulating layer in the first region R1.

The insulating liner 121 may include oxide or nitride. For example, the insulating liner 121 may include silicon oxide. The insulating liner 121 may include a high-k material. A high dielectric constant material may refer to a dielectric material having a higher dielectric constant than a silicon oxide film (SiO₂). For example, the high dielectric constant material may be any one of aluminum oxide (Al₂O₃), tantalum oxide (Ta₂O₃), titanium oxide (TiO₂), yttrium oxide (Y₂O₃), zirconium oxide (ZrO₂), zirconium silicon oxide (ZrSiₓO_{y}), hafnium oxide (HfO₂), hafnium silicon oxide (HfSiₓO_{y}), Lanthanum oxide (La₂O₃), lanthanum aluminum oxide (LaAlₓO_{y}), lanthanum hafnium oxide (LaHfₓO_{y}), hafnium aluminum oxide (HfAlₓO_{y}), and praseodymium oxide (Pr₂O₃). The insulating liner 121 may be composed of a plurality of insulating films, and each of the plurality of insulating films may include one of the above-mentioned materials.

The gate pad 190 may be disposed/formed on the third region R3 on the substrate 101. In an example, the third region R3 may be adjacent to the first region R1 in the first direction (X-direction). In an example, the gate pad 190 may be disposed on one side of the gate electrodes 130 and electrically connected to the gate electrodes 130 through gate bus lines 160. The gate pad 190 is electrically connected to the pad metal layer disposed thereon and may receive an electrical signal through the pad metal layer. In an example, some of the gate electrodes 130 may extend to a lower portion of the gate pad 190 and may overlap and be electrically connected to the gate pad 190 in the vertical direction (Z-direction). Depending on example embodiments, the shape of the gate pad 190 may be a square, circular, or oval shape in a plan view.

The gate bus lines 160 may be disposed and/or formed on the second region R2 on the substrate 101. The second region R2 may include regions surrounding one side extending in the first direction (X-direction) of the first region R1 and the other side parallel to one side of the first region R1. In an example, the second region R2 may be an area surrounding the first region R1 and the periphery of the third region R3 disposed on one side of the first region R1.

The power semiconductor device 100 may include a plurality of gate bus lines 160. For example, the power semiconductor device may include two gate bus lines 160. The gate bus lines 160 may connect one end of each of the gate electrodes 130 and the other end opposite to one end of each of the gate electrodes 130. In an example, the gate bus lines 160 may be disposed symmetrically about the X-axis with the gate pad 190 as the center. In an example, the gate bus lines 160 may include a first part connected to the gate pad 190 and extending in the second direction (Y-direction), and a second part extending from the first part in a first direction (X-direction) intersecting the second direction (Y-direction), which is the extension direction of the gate electrodes 130. The gate bus lines 160 may be connected to the conductive pattern 135 in the vertical direction (Z-direction) through the gate contact plug 145 penetrating through the dielectric layer 125.

The gate pad 190 and the gate bus lines 160 may include a conductive material, for example, a metal material. The gate pad 190 and the gate bus lines 160 may include at least one of, for example, titanium nitride (TiN), titanium (Ti), titanium carbide (TIC), tantalum nitride (TaN), tungsten nitride (WN), aluminum (Al), tungsten (W), and molybdenum (Mo). In an example, the gate pad 190 and the gate bus lines 160 may include the same material or different materials.

The insulating pattern 123 may be disposed on a portion of the insulating liner 121 disposed on the second region R2. The insulating pattern 123 may overlap the second well region 105b disposed on the second region R2 in the vertical direction (Z-direction). The insulating pattern 123 may be disposed in a ring shape to surround the first region R1 on the second region R2. However, the present disclosure is not limited thereto. For example, the insulating pattern 123 may be disposed in the form of an open curved line. In an example, the upper surface of the insulating pattern 123 may be disposed at a lower level than the upper surface of the gate electrode 130. However, the present disclosure is not limited thereto, and the upper surface of the insulating pattern 123 may be disposed on substantially the same level as the upper surface of the gate electrode 130.

The insulating pattern 123 may include an insulating material, and for example, may include oxide or nitride. The insulating pattern 123 may include a silicon oxide film (SiO₂).

The conductive pattern 135 may be disposed on the insulating liner 121 and the insulating pattern 123 to be spaced apart from the gate electrodes 130. In an example, the conductive pattern 135 may be disposed on a region of the insulating liner 121 and the insulating pattern 123 between the gate electrodes 130 and the insulating pattern 123. In an example, the conductive pattern 135 may include a first pattern 135a overlapping the insulating liner 121 in the vertical direction (Z-direction) and a second pattern 135b extending from the first pattern 135a and overlapping the insulating pattern 123. In an example, the first pattern 135a may contact the upper surface of the insulating liner 121 disposed on the second well region 105b. The second pattern 135b covers a portion of the insulating pattern 123 and may be in contact with the upper surface of the portion of the insulating pattern 135b.

The upper surface of the conductive pattern 135 may be disposed on the same level as the upper surface of the gate electrodes 130. In an example, the upper surface of the first pattern 135a and the upper surface of the second pattern 135b may be disposed on the same level.

The first pattern 135a may have a first height H1 in the vertical direction (Z-direction) on the insulating liner 121 disposed on the second well region 105b. The second pattern 135b may have a second height H2 that is shorter than the first height H1 in the vertical direction (Z-direction) on the insulating pattern 123. In an example, the gate electrodes 130 may have a height equal to the first height H1 in the vertical direction (Z-direction) on the insulating liner 121 disposed on the first well region 105a.

A portion of the first pattern 135a may overlap the first peripheral contact region 109a in the second well region 105b in the vertical direction (Z-direction).

The conductive pattern 135 may include a conductive material, for example, a semiconductor material such as doped polycrystalline silicon, a metal nitride, such as titanium nitride (TiN), tantalum nitride (TaN), or tungsten nitride (WN), and/or a metallic substance such as aluminum (Al), tungsten (W), or molybdenum (Mo). Depending on example embodiments, the conductive pattern 135 may be composed of two or more layers. In an example, the conductive pattern 135 may include the same material as the gate electrodes 130. However, the present disclosure is not limited thereto, and the conductive pattern 135 may include a conductive material different from that of the gate electrodes 130.

The dielectric layer 125 may cover a portion of the insulating liner 121, the gate electrodes 130, and the conductive pattern 135. The dielectric layer 125 may include an insulating material and may include at least one of silicon oxide, silicon nitride, and silicon oxynitride.

A source electrode 150 and a gate bus line 160 may be disposed on the dielectric layer 125. The source electrode 150 may be disposed on the first region R1 of the substrate 101, and the gate bus line 160 may be disposed on the second region R2 and spaced apart from the source electrode 150 in the first direction (X-direction).

The source electrode 150 may be disposed on the dielectric layer 125 and may be electrically connected to the source regions 107 and the well contact region 108 through the source contact plug 141. The source electrode 150 may be disposed on the dielectric layer 125 and electrically connected to the first peripheral contact region 109a through the first peripheral contact plug 143.

The source electrode 150 may include a metallic substance, for example, contain at least one of nickel (Ni), aluminum (Al), titanium (Ti), silver (Ag), vanadium (V), tungsten (W), cobalt (Co), molybdenum (Mo), copper (Cu), and ruthenium (Ru).

The source contact plug 141 may penetrate the dielectric layer 125 and be disposed between the source electrode 150 and the source regions 107 of the first well region 105a. In an example, the source contact plug 141 may be disposed between the gate electrodes 130. The source contact plug 141 may include a conductive plug. The conductive plug may include a metal material, for example, tungsten (W), titanium (Ti), aluminum (Al), or copper (Cu).

A first metal-semiconductor compound layer 152a may be disposed at the interface in contact with the source contact plug 141, the source regions 107, and the well contact region 108.

The dielectric layer 125 may include a side 125S1 surrounding the side surface of the source contact plug 141 and an upper surface 125S2 extending from the side 125S1 and contacting the source electrode 150. The dielectric layer 125 may include a corner formed in an area where the side 125S1 and the upper surface 125S2 contact each other.

The dielectric layer 125 may expose the upper surface of the source contact plug 141. In an example, the upper surface of the source contact plug 141 may be disposed on substantially the same level as the upper surface of the dielectric layer 125.

The gate bus line 160 may be connected to the conductive pattern 135 through the gate contact plug 145. The gate contact plug 145 may connect the gate bus line 160 and the conductive pattern 135 by penetrating through the dielectric layer 125. The gate contact plug 145 may contact the upper surface of the second pattern 135b of the conductive pattern 135.

The dielectric layer 125 may expose the upper surface of the gate contact plug 145. In an example, the upper surface of the gate contact plug 145 may be disposed on the same level as the upper surface of the dielectric layer 125. In an example, the upper surface of the gate contact plug 145 may be disposed on the same level as the upper surface of the source contact plug 141.

The power semiconductor device 100 according to example embodiments may further include a conductive terminal 170 disposed on the dielectric layer 125, a first peripheral contact plug 143 disposed between the gate electrode 130 and the conductive pattern 135, and a second peripheral contact plug 147 disposed between the conductive terminal 170 and the second well region 105b.

The first peripheral contact plug 143 may penetrate the dielectric layer 125 to connect the source electrode 150 and the first peripheral contact region 109a of the second well region 105b. The second peripheral contact plug 147 may connect the conductive terminal 170 and the second peripheral contact region 109b by penetrating through the dielectric layer 125 and the insulating pattern 123.

A second metal-semiconductor compound layer 152b may be disposed at an interface that contacts the first peripheral contact plug 143 and the first peripheral contact region 109a. A third metal-semiconductor compound layer 152c may be disposed at an interface that contacts the second peripheral contact plug 147 and the second peripheral contact region 109b.

The metal-semiconductor compound layers 152a, 152b, and 153c may include a metal element and a semiconductor element, for example, at least one of TiSi, CoSi, MoSi, LaSi, NiSi, TaSi, or Wsi.

The upper surfaces of the first and second peripheral contact plugs 143 and 147 may be disposed on the same level as the upper surface of the dielectric layer 125.

The upper surfaces of the source contact plug 141, the gate contact plug 145, and the first and second peripheral contact plugs 143 and 147 may be disposed on the same level.

The source electrode 150, gate bus line 160, and conductive terminal 170 may be in contact with the upper surface of the dielectric layer 125.

The lower surface of the source electrode 150 and the lower surface of the gate bus line 160 may be disposed on the same level.

The power semiconductor device 100 according to example embodiments may include a conductive pattern 135 having an upper surface disposed on the same level as the upper surface of the gate electrodes 130 disposed in the first region R1 and extending from the first region R1 and disposed in the second region R2, a source electrode 150 disposed in the first region R1 on the upper surface of the dielectric layer 125 having corners, and a gate bus line 160 disposed in the second region R2. Accordingly, the power semiconductor device 100 may prevent cracks or inflow of foreign substances due to the step difference between the first region R1 (cell region) and the second region R2 (edge region), thereby providing power semiconductor devices having improved reliability.

According to example embodiments, at least one of the source contact plug 141 and the first peripheral contact plug 143 may include the same material as the source electrode 150. At least one of the source contact plug 141 and the first peripheral contact plug 143 may be integrated with the source electrode 150, and the interface between the two may not be identified. Similarly, the gate bus line 160 and the gate contact plug 145 may include the same material, and may be formed integrally, and the interface therebetween may not be discernible. Additionally, the conductive terminal 170 and the second peripheral contact plug 147 may include the same material, and may be formed as one body, and the interface between the two may not be identifiable.

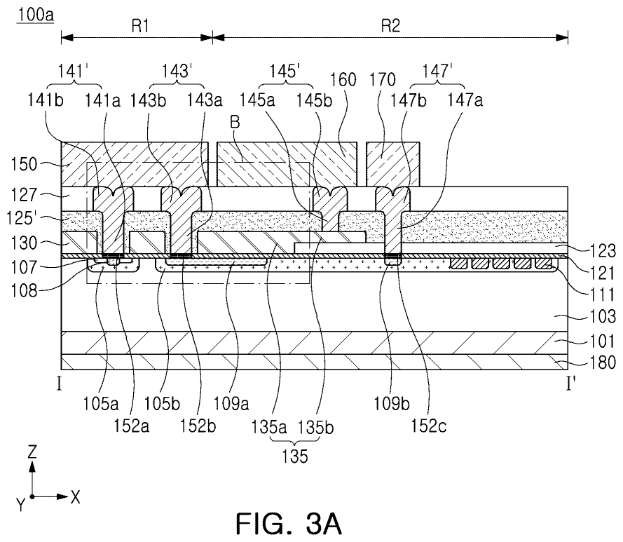

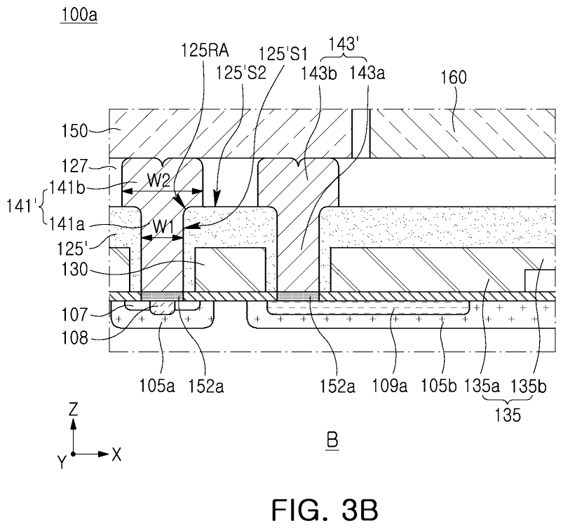

FIG. 3A is a cross-sectional view illustrating another embodiment of the power semiconductor device of FIG. 1 along line I-I′. FIG. 3B is an enlarged view of region B of the power semiconductor device of FIG. 3A.

Referring to FIG. 3A, the components of a power semiconductor device 100a, except for the dielectric layer 125′, the interlayer insulating layer 127, the source contact plug 141′, the gate contact plug 145′, and the first and second peripheral contact plugs 143′ and 147′ may be the same as or similar to the configurations of the power semiconductor device 100 of FIG. 2A.

The power semiconductor device 100a may include gate electrodes 130, a conductive pattern 135, a dielectric layer 125′ covering the gate electrodes 130 and the conductive pattern 135, and an interlayer insulating layer 127 disposed on the dielectric layer 125′. The power semiconductor device 100a may include a source contact plug 141′, a gate contact plug 145′, and first and second peripheral contact plugs 143′ and 147′ penetrating through the dielectric layer 125′ and the interlayer insulating layer 127.

The power semiconductor device 100a may include a conductive pattern 135 having an upper surface disposed on the same level as the upper surface of the gate electrodes 130. In an example, the upper surfaces of the first pattern 135a and the second pattern 135b of the conductive pattern 135 may be disposed on substantially the same level as the upper surfaces of the gate electrodes 130.

The dielectric layer 125′ may cover the gate electrodes 130 and the conductive pattern 135. An interlayer insulating layer 127 may be disposed on the dielectric layer 125′.

A source electrode 150, a gate bus line 160, and a conductive terminal 170 may be disposed on the interlayer insulating layer 127.

The interlayer insulating layer 127 may include an insulating material, for example, at least one of silicon oxide, silicon nitride, and silicon oxynitride.

The source electrode 150 may be connected to the source regions 107 and the well contact region 108 through a source contact plug 141′ penetrating through the dielectric layer 125′ and the interlayer insulating layer 127. In an example, the source electrode 150 may be connected to the first peripheral contact region 109a through the first peripheral contact plug 143′ penetrating through the dielectric layer 125′ and the interlayer insulating layer 127.

The gate bus line 160 may be connected to the conductive pattern 135 through a gate contact plug 145′ penetrating through the dielectric layer 125′ and the interlayer insulating layer 127.

The conductive terminal 170 may be connected to the second peripheral contact region 109b through the second peripheral contact plug 147′ penetrating through the dielectric layer 125′ and the interlayer insulating layer 127.

The source contact plug 141′ may include a first source contact plug portion 141a penetrating through the dielectric layer 125′ and a second source contact plug portion 141b penetrating through the interlayer insulating layer 127. In an example, a side surface of the first source contact plug portion 141a may be surrounded by a dielectric layer 125′, and the first source contact plug portion 141a may have a first width W1 in the horizontal direction. A side surface of the second source contact plug portion 141b may be surrounded by an interlayer insulating layer 127, and the second source contact plug portion 141b may have a second width W2 that is larger than the first width W1 in the horizontal direction.

The gate contact plug 145′ may include a first gate contact plug portion 145a penetrating through the dielectric layer 125′ and a second gate contact plug portion 145b penetrating through the interlayer insulating layer 127. The side surface of the first gate contact plug portion 145a may be surrounded by the dielectric layer 125′, and the side surface of the second gate contact plug portion 145b may be surrounded by the interlayer insulating layer 127. In an example, the width of the second gate contact plug portion 145b in the horizontal direction may be larger than the width of the first gate contact plug portion 145a in the horizontal direction.

The first peripheral contact plug 143′ may include a 1-1 peripheral contact plug portion 143a penetrating through the dielectric layer 125′ and a 1-2 peripheral contact plug portion 143b penetrating through the interlayer insulating layer 127.

The second peripheral contact plug 147′ may include a 2-1 peripheral contact plug portion 147a penetrating through the dielectric layer 125′ and a 2-2 peripheral contact plug portion 147b penetrating through the interlayer insulating layer 127.

In an example, the side of the 1-1 peripheral contact plug portion 143a and the 2-1 peripheral contact plug portion 147a may be surrounded by the dielectric layer 125′. The side surface of the 1-2 peripheral contact plug portion 143b and the side surface of the 2-2 peripheral contact plug portion 147b may be surrounded by the interlayer insulating layer 127.

The dielectric layer 125′ may include a side 125′S1 surrounding the side of the first source contact plug portion 141a, an upper surface 125′S2 in contact with the lower surface of the second source contact plug portion 141b and the lower surface of the interlayer insulating layer 127, and a curved area 125RA connecting the side 125′S1 and upper surface 125′S2. The curved area 125RA may have a predetermined curvature.

The power semiconductor device 100a according to example embodiments includes a conductive pattern 135 extending from the first region R1 and disposed in the second region R2 and having an upper surface disposed on the same level as the upper surface of the gate electrodes 130 disposed in the first region R1, and thus the step difference between the first region R1 and the second region R2 may be significantly reduced, thereby providing a power semiconductor device having improved reliability.

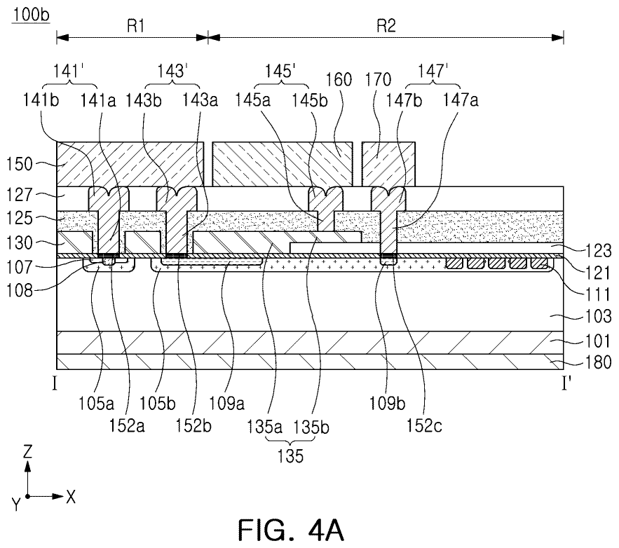

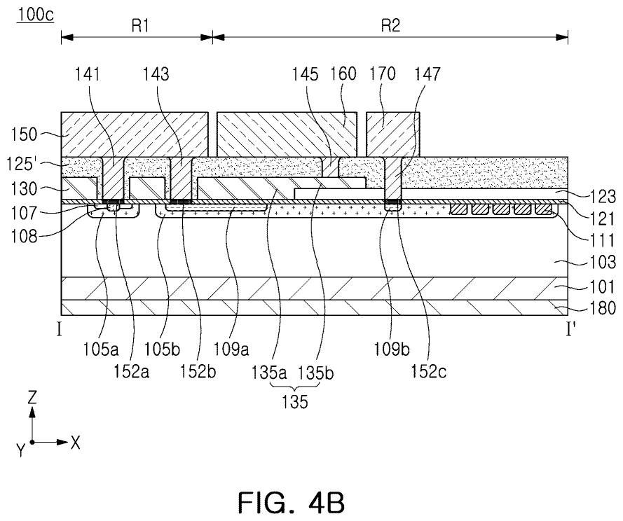

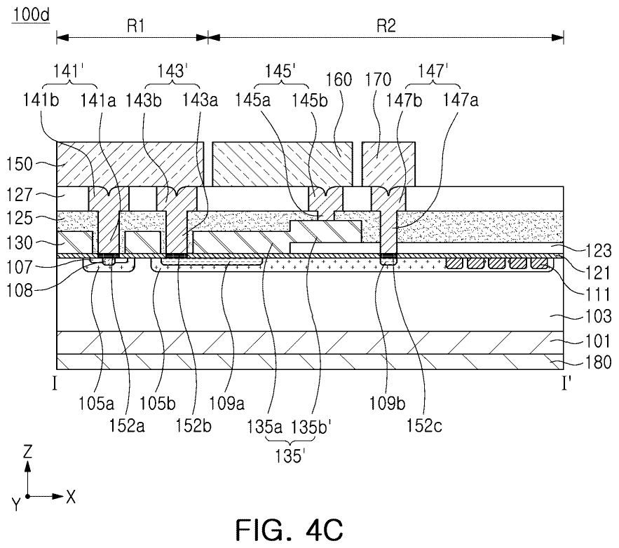

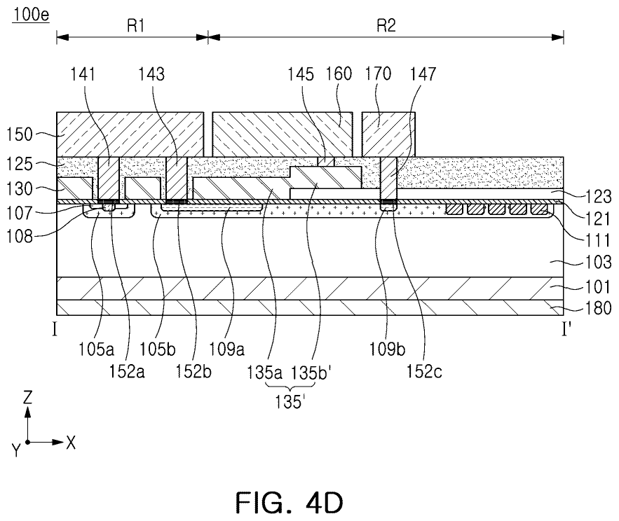

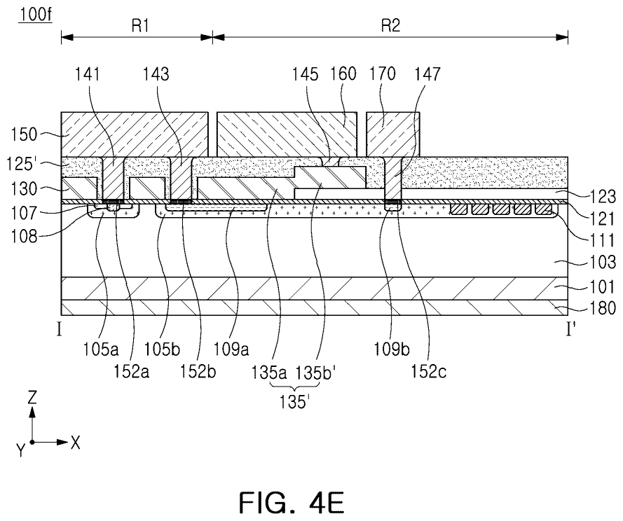

FIGS. 4A to 4E are cross-sectional views illustrating another embodiment of the power semiconductor device of FIG. 1 along line I-I′.

Referring to FIG. 4A, the remaining configurations of a power semiconductor device 100b, except for the dielectric layer 125, may be the same or similar to the configurations of the power semiconductor device 100a of FIG. 3A.

The power semiconductor device 100b may include gate electrodes 130, a conductive pattern 135, a dielectric layer 125 covering the gate electrodes 130 and the conductive pattern 135, and an interlayer insulating layer 127 disposed on the dielectric layer 125. In an example, the power semiconductor device 100b may include a source contact plug 141′, a gate contact plug 145′, and first and second peripheral contact plugs 143′ and 147′ penetrating through the dielectric layer 125 and the interlayer insulating layer 127.

The power semiconductor device 100b may include a conductive pattern 135 having an upper surface disposed on the same level as the upper surface of the gate electrodes 130.

The dielectric layer 125 may cover the gate electrodes 130 and the conductive pattern 135. An interlayer insulating layer 127 may be disposed on the dielectric layer 125.

A source electrode 150, a gate bus line 160, and a conductive terminal 170 may be disposed on the interlayer insulating layer 127.

The source electrode 150 may be connected to the source regions 107 and the well contact region 108 through a source contact plug 141′ penetrating through the dielectric layer 125 and the interlayer insulating layer 127. In an example, the source electrode 150 may be connected to the first peripheral contact region 109a through the first peripheral contact plug 143′ penetrating through the dielectric layer 125 and the interlayer insulating layer 127.

The gate bus line 160 may be connected to the conductive pattern 135 through a gate contact plug 145′ penetrating through the dielectric layer 125 and the interlayer insulating layer 127.

The conductive terminal 170 may be connected to the second peripheral contact region 109b through the second peripheral contact plug 147′ penetrating through the dielectric layer 125 and the interlayer insulating layer 127.

The conductive terminal 170 may be connected to the second peripheral contact region 109b through the second peripheral contact plug 147′ penetrating through the dielectric layer 125 and the interlayer insulating layer 127.

The source contact plug 141′ may include a first source contact plug portion 141a penetrating through the dielectric layer 125 and a second source contact plug portion 141b penetrating through the interlayer insulating layer 127.

The gate contact plug 145′ may include a first gate contact plug portion 145a penetrating through the dielectric layer 125 and a second gate contact plug portion 145b penetrating through the interlayer insulating layer 127.

The first peripheral contact plug 143′ may include a 1-1 peripheral contact plug portion 143a penetrating through the dielectric layer 125 and a 1-2 peripheral contact plug portion 143b penetrating through the interlayer insulating layer 127.

The second peripheral contact plug 147′ may include a 2-1 peripheral contact plug portion 147a penetrating through the dielectric layer 125 and a 2-2 peripheral contact plug portion 147b penetrating through the interlayer insulating layer 127.

The dielectric layer 125 may include a side surrounding the side of the first source contact plug portion 141a (for example, side 125S1 in FIG. 2B), and an upper surface extending from the side and contacting the lower surface of the second source contact plug portion 141b and the lower surface of the interlayer insulating layer 127 (for example, upper surface 125S2 in FIG. 2B). The dielectric layer 125 may include a corner formed in an area where the side and upper surfaces come into contact.

The power semiconductor device 100b according to example embodiments may include a conductive pattern 135 extending from the first region R1 and disposed in the second region R2 and having an upper surface disposed on the same level as the upper surfaces of the gate electrodes 130 disposed in the first region R1, and a dielectric layer 125 having a corner. Accordingly, a power semiconductor device having improved reliability may be provided by significantly reducing the step difference between the first region R1 and the second region R2.

Referring to FIG. 4B, the remaining configurations of a power semiconductor device 100c, except for the dielectric layer 125′, may be the same or similar to the configurations of the power semiconductor device 100 of FIG. 2A.

The power semiconductor device 100c may include gate electrodes 130, conductive patterns 135, a dielectric layer 125′ covering the gate electrodes 130 and the conductive pattern 135, and a source electrode 150, a gate bus line 160 and a conductive terminal 170 disposed on the dielectric layer 125′.

The source electrode 150, gate bus line 160, and conductive terminal 170 may be in contact with the upper surface of the dielectric layer 125′.

The source electrode 150 may be connected to the source regions 107 and the well contact region 108 through the source contact plug 141 penetrating through the dielectric layer 125′. In an example, the source electrode 150 may be connected to the first peripheral contact region 109a through the first peripheral contact plug 143 penetrating through the dielectric layer 125′.

The gate bus line 160 may be connected to the conductive pattern 135 through the gate contact plug 145 penetrating through the dielectric layer 125′.

The conductive terminal 170 may be connected to the second peripheral contact region 109b through the second peripheral contact plug 147 penetrating through the dielectric layer 125′.

The dielectric layer 125′ may include a side surrounding the side of the source contact plug 141 (for example, side 125′S1 in FIG. 3B), an upper surface in contact with the lower surface of the source electrode 150 (for example, upper surface 125′S2 in FIG. 3B), and a curved area extending from the side and connected to the upper surface (for example, curved area 125RA in FIG. 3B). The curved area may have a predetermined curvature.

Each side of the source contact plug 141, the gate contact plug 145, and the first and second peripheral contact plugs 143 and 147 may be surrounded by a dielectric layer 125′.

The upper surface of the source contact plug 141 may be disposed on the same level as the upper surface of the dielectric layer 125′. In an example, the upper surface of the gate contact plug 145 and the upper surfaces of the first and second peripheral contact plugs 143 and 147 may be disposed on the same level as the upper surface of the dielectric layer 125′.

The power semiconductor device 100c according to example embodiments includes a conductive pattern 135 extending from the first region R1 and disposed in the second region R2, and having an upper surface disposed on the same level as the upper surface of the gate electrodes 130 disposed in the first region R1, a source contact plug 141 having an upper surface disposed on the same level as the upper surface of the dielectric layer 125′, a gate contact plug 145, and first and second peripheral contact plugs 143 and 147. Therefore, the step difference between the first region R1 and the second region R2 may be significantly reduced, thereby providing power semiconductor devices having improved reliability.

Referring to FIG. 4C, the remaining components of a power semiconductor device 100d, excluding the conductive pattern 135′, the interlayer insulating layer 127, the source contact plug 141′, the gate contact plug 145′, and the first and second peripheral contact plugs 143′ and 147′ may be the same or similar to the configurations of the power semiconductor device 100 of FIG. 2A.

The power semiconductor device 100d may include gate electrodes 130, a conductive pattern 135′, a dielectric layer 125 covering the gate electrodes 130 and the conductive pattern 135′, and an interlayer insulating layer 127 disposed on the dielectric layer 125. In an example, the power semiconductor device 100d may include a source contact plug 141′, a gate contact plug 145′, and first and second peripheral contact plugs 143′ and 147′ penetrating through the dielectric layer 125 and the interlayer insulating layer 127.

The conductive pattern 135′ may be disposed on a portion of the insulating liner 121 and the insulating pattern 123 and spaced apart from the gate electrodes 130. In an example, the conductive pattern 135′ may include a first pattern 135a in contact with the upper surface of the insulating liner 121, and a second pattern 135b′ extending from the first pattern 135a and in contact with a portion of the insulating pattern 123.

The height of the first pattern 135a in the vertical direction (Z-direction) from the upper surface of the insulating liner 121 may be substantially equal to the height of the second pattern 135b′ in the vertical direction (Z-direction) from the upper surface of the insulating pattern 123.

The upper surface of the first pattern 135a may be disposed at a lower level than the upper surface of the second pattern 135b′. In an example, the upper surface of the second pattern 135b′ may be disposed at a level higher than the upper surface of the first pattern 135a by the height of the insulating pattern 135b′ in the vertical direction (Z-direction).

The upper surface of the first pattern 135a may be disposed on the same level as the upper surface of the gate electrode 130. In an example, the upper surface of the second pattern 135b′ may be disposed at a higher level than the upper surface of the gate electrode 130.

The dielectric layer 125 may cover the gate electrode 130 and the conductive pattern 135′.

The power semiconductor device 100d according to example embodiments includes a dielectric layer 125 having corners, thereby significantly reducing the step difference between the first region R1 and the second region R2 and thus providing power semiconductor devices having improved reliability.

Referring to FIG. 4D, the remaining configurations of a power semiconductor device 100e, except for the conductive pattern 135′, may be the same or similar to those of the power semiconductor device 100 of FIG. 2A.

The power semiconductor device 100e according to example embodiments includes a dielectric layer 125 having a corner, a source contact plug 141, a gate contact plug 145 and first and second peripheral contact plugs 143 and 147 having an upper surface disposed on the same level as the upper surface of the dielectric layer 125, thereby significantly reducing the step difference between the first region R1 and the second region R2 and thus providing a power semiconductor device having improved reliability.

Referring to FIG. 4E, the remaining configurations of a power semiconductor device 100f, except for the conductive pattern 135′ and the dielectric layer 125′, may be the same as or similar to those of the power semiconductor device 100 of FIG. 2A.

The power semiconductor device 100f according to example embodiments includes a source contact plug 141, a gate contact plug 145, and first and second peripheral contact plugs 143 and 147 having an upper surface disposed on the same level as the upper surface of the dielectric layer 125′, thereby significantly reducing the step difference between the first region R1 and the second region R2 and thus providing power semiconductor devices having improved reliability.

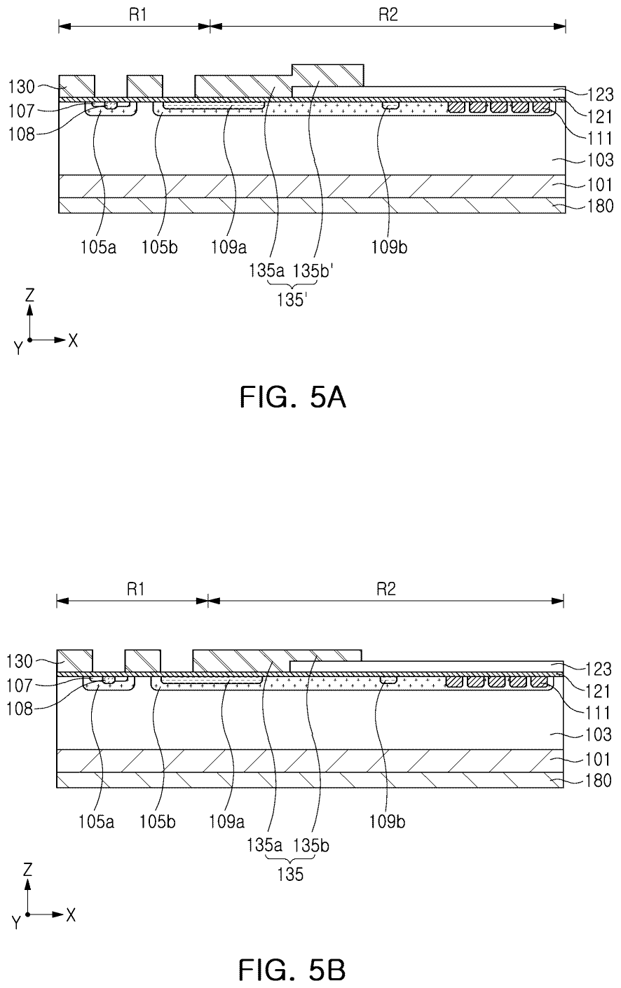

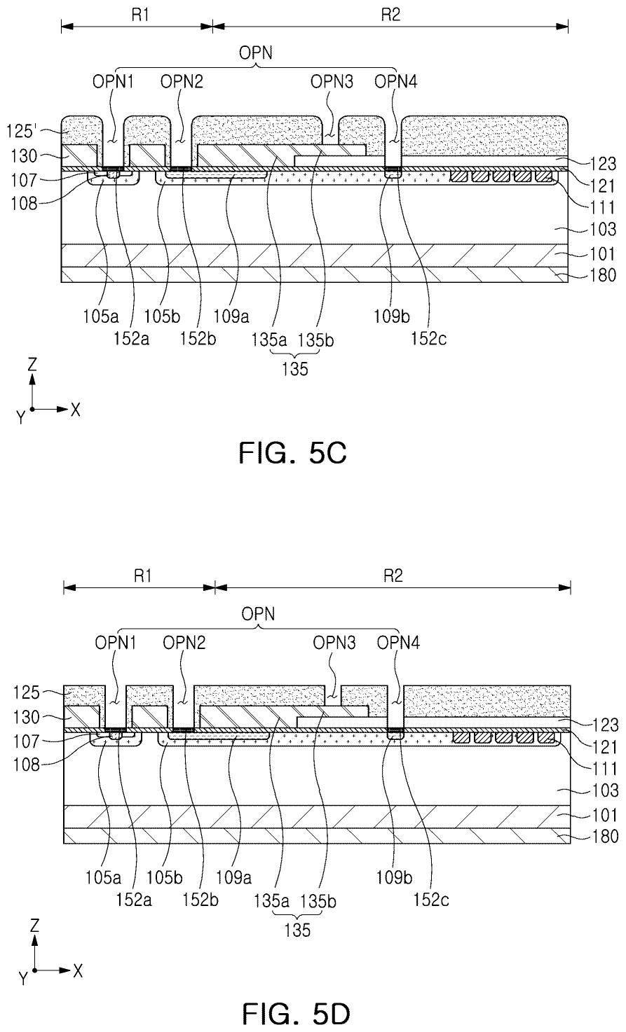

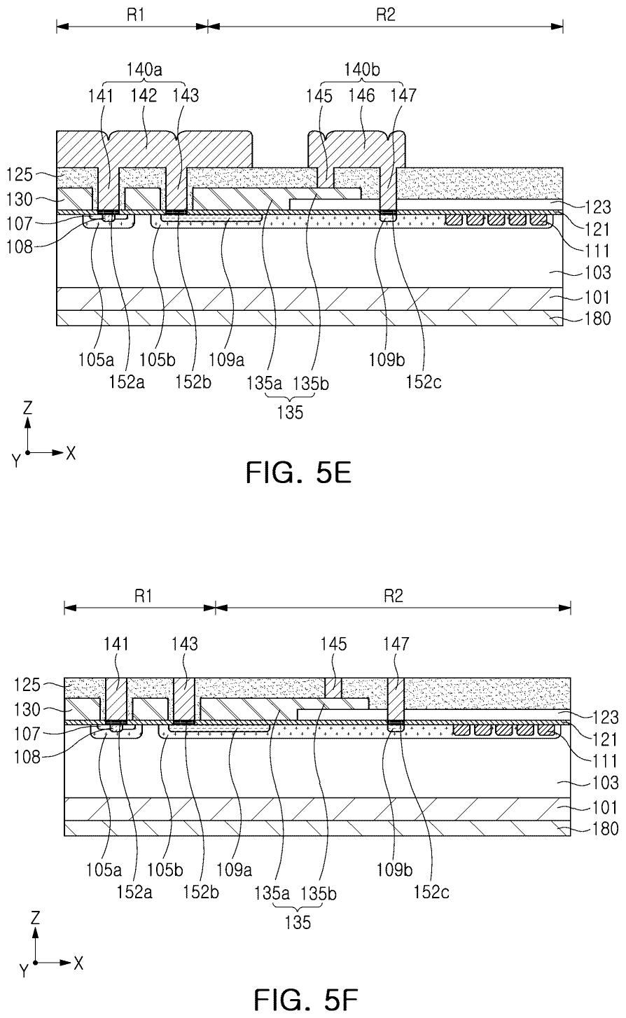

FIGS. 5A to 5F are diagrams illustrating an example embodiment of the method of manufacturing the power semiconductor device of FIG. 2A.

Referring to FIG. 5A, a method of manufacturing method a power semiconductor device may include forming a drift layer 103 on the substrate 101, and forming first and second well regions 105a and 105b, source regions 107 and well contact regions 108 in the first well region 105a and first and second peripheral contact regions 109a and 109b within second well region 105b.

The manufacturing method may include forming an insulating liner 121 on the first and second well regions 105a and 105b, and forming an insulating pattern 123 on the insulating liner 121 formed on the second well region 105b.

The manufacturing method may include forming gate electrodes 130 spaced apart from each other in the first direction (X-direction) with the source regions 107 interposed therebetween, on the insulating liner 121 formed on the first well region 105a. The manufacturing method may include forming a conductive pattern 135′ spaced apart from the gate electrodes 130 and covering at least a portion of the insulating liner 121 and the insulating pattern 123 formed on the second well region 105b.

The conductive pattern 135′ may include a first pattern 135a in contact with the upper surface of the insulating liner 121 formed on the second well region 105b, and a second pattern 135b′ in contact with the upper surface of the insulating pattern 123. The heights of the first pattern 135a and the second pattern 135b′ in the vertical direction may be substantially the same as each other.

In an example, the upper surface of the first pattern 135a of the conductive pattern 135′ may be disposed on substantially the same level as the upper surface of the gate electrode 130.

The conductive pattern 135′ may be formed in the same process as the gate electrodes 130. In an example, the gate electrodes 130 and conductive pattern 135′ may be deposited using deposition techniques such as chemical vapor deposition (CVD), plasma enhanced chemical vapor deposition (PE-CVD), or spin on dielectric (SOD).

Referring to FIG. 5B, the manufacturing method may include forming a conductive pattern 135 by performing a chemical mechanical polishing (CMP) process to flatten the conductive pattern 135. The conductive pattern 135 may be formed by etching the second pattern 135b of the conductive pattern 135 in the vertical direction (Z-direction) to have the same level as the upper surface of the first pattern 135a. In an example, upper surfaces of the first pattern 135a and the second pattern 135b of the conductive pattern 135 may be coplanar.

Referring to FIG. 5C, the manufacturing method may include removing a portion of the insulating liner 121 to expose a portion of the source regions 107, the well contact region 108, and the first and second peripheral contact regions 109a, 109b.

The manufacturing method may include forming parts of source regions 107 and well contact region 108, and metal-semiconductor compound layers 152a, 152b, and 152c on the first and second peripheral contact regions 109a and 109b, respectively.

The method may include forming a dielectric layer 125′ covering the gate electrodes 130 and the conductive pattern 135. The metal-semiconductor compound layers 152a, 152b, and 152c may be exposed through the openings OPN formed in the dielectric layer 125′.

The dielectric layer 125′ may include a side of the openings OPN (for example, side 125′S1 in FIG. 3B) and an upper surface extending from the side (for example, upper surface 125′S2 in FIG. 3B), and may include a curved area connecting the side surface to the upper surface (for example, the curved area 125RA in FIG. 3B).

Referring to FIG. 5D, the step difference of forming a flattened dielectric layer 125 by performing a chemical mechanical polishing (CMP) process to remove the curved area of the dielectric layer 125′ may be included. The dielectric layer 125′ may be formed as a dielectric layer 125 having corners through the CMP process.

Referring to FIG. 5E, forming plug structures 140a and 140b that fill the openings OPN may be included.

The plug structures 140a and 140b may include a first plug structure 140a filling the first and second openings OPN1 and OPN2, and second plug structures 140b filling the third and fourth openings OPN3 and OPN4.

The first plug structure 140a may include a source contact plug 141 filling the first opening OPN1 exposing the first metal-semiconductor compound layer 152a disposed on the source regions 107 and the well contact region 108, a first peripheral contact plug 143 filling the second opening OPN2 exposing the second metal-semiconductor compound layer 152b disposed on the first peripheral contact region 109a, and a first conductive structure 142 formed on the dielectric layer 125 and integrated with the source contact plug 141 and the first peripheral contact plug 143.

The second plug structure 140b may include a gate contact plug 145 filling the third opening OPN3 exposing a portion of the conductive pattern 135, a second peripheral contact plug 147 filling the fourth opening OPN4 exposing the third metal-semiconductor compound layer 152c disposed on the second peripheral contact region 109b, and a second conductive structure 146 formed on the dielectric layer 125 and integrated with the gate contact plug 145 and the second peripheral contact plug 147.

The first and second plug structures 140a and 140b are illustrated to be formed spaced apart in the first direction (X-direction), but are not limited thereto. The first plug structure 140a and the second plug structure 140b may be formed integrally. The first and second plug structures 140a and 140b may be formed through a plating process, a PVD process, or a CVD process.

Referring to FIG. 5F, a CMP process may be performed to remove the first conductive structure 142 and the second conductive structure 146 formed on the dielectric layer 125.

By the CMP process, upper surfaces of the source contact plug 141, the gate contact plug 145, and the first and second peripheral contact plugs 143 and 147 may be formed to have the same level. In an example, the upper surfaces of the gate contact plug 145 and the first and second peripheral contact plugs 143 and 147 may be formed to have the same level as the upper surface of the dielectric layer 125.

A method of manufacturing a power semiconductor device according to example embodiments may include a planarization process operation for the conductive pattern 135 formed over the first region R1 and the second region R2, a planarization process operation for the dielectric layer 125 covering the gate electrodes 130 and the conductive pattern 135, and a planarization process operation for the source contact plug 141 to electrically connect the source electrode 150 formed on the dielectric layer 125 to the source regions 107, and thus, the step difference between the first and second regions R1 and R2 may be removed, thereby providing power semiconductor devices having improved reliability.

As set forth above, power semiconductor devices according to example embodiments may include a conductive pattern, a dielectric layer, and a contact plug disposed in a connection region extending from the cell region, and at least one of the conductive pattern, the dielectric layer, and the contact plug may be planarized by a polishing process. Accordingly, the power semiconductor device may have improved reliability by improving the step difference between a cell region and the connection region.

While example embodiments have been illustrated and described above, it will be apparent to those skilled in the art that modifications and variations could be made without departing from the scope of the appended claims.

What is claimed is:

1. A power semiconductor device comprising:
a substrate including a cell region and an edge region extending from the cell region;
a drift layer of a first conductivity type on the substrate;
a first well region of a second conductivity type extending from an upper surface of the drift layer in the cell region and further disposed within the drift layer;
a source region of the first conductivity type extending from an upper surface of the first well region and further disposed within the first well region;
an insulating liner on the drift layer;
gate electrodes spaced apart from each other on the insulating liner in the cell region, with the source region interposed between the gate electrodes;
an insulating pattern in the edge region;
a conductive pattern spaced apart from the gate electrodes and covering a portion of the insulating liner and further covering a portion of the insulating pattern;
a dielectric layer covering the gate electrodes and further covering the conductive pattern;
a source electrode on the dielectric layer; and
a source contact plug penetrating through the dielectric layer and connecting the source electrode and the source region,
wherein the conductive pattern includes a first pattern in contact with the insulating liner and a second pattern in contact with the insulating pattern, and an upper surface of the first pattern is disposed on a same level as an upper surface of the second pattern.

2. The power semiconductor device of claim 1, wherein an upper surface of the dielectric layer is disposed on a same level as an upper surface of the source contact plug.

3. The power semiconductor device of claim 1, wherein the source electrode contacts a portion of an upper surface of the dielectric layer and further contacts an upper surface of the source contact plug.

4. The power semiconductor device of claim 1, further comprising an interlayer insulating layer on the dielectric layer,
wherein the source contact plug includes a first source contact plug portion surrounded by the dielectric layer and a second source contact plug portion extending from the first source contact plug portion and surrounded by the interlayer insulating layer.

5. The power semiconductor device of claim 4, wherein a width of the first source contact plug portion in a first direction is smaller than a width of the second source contact plug portion in the first direction.

6. The power semiconductor device of claim 1, wherein the dielectric layer includes a side in contact with the source contact plug, an upper surface extending from the side, and a corner where the side and the upper surface are in contact.

7. The power semiconductor device of claim 1, wherein the dielectric layer includes a side in contact with the source contact plug, an upper surface extending from the side, and a curved area between the side and the upper surface.

8. The power semiconductor device of claim 1, further comprising:
a gate bus line spaced apart from the source electrode and disposed in the edge region; and
a gate bus line contact plug penetrating through the dielectric layer and connecting the gate bus line and the conductive pattern.

9. The power semiconductor device of claim 8, wherein a lower surface of the source electrode is disposed on a same level as a lower surface of the gate bus line.

10. The power semiconductor device of claim 8, wherein the gate bus line contact plug overlaps the second pattern in a vertical direction.

11. The power semiconductor device of claim 1, further comprising a well contact region of the second conductivity type extending from the upper surface of the first well region, disposed within the first well region, and crossing the source region.

12. The power semiconductor device of claim 1, further comprising a second well region of the second conductivity type spaced apart from the first well region, extending from the upper surface of the drift layer in the edge region, and disposed within the drift layer,
wherein the conductive pattern overlaps the second well region.

13. The power semiconductor device of claim 12, further comprising guard rings of the second conductivity type spaced apart from the conductive pattern in a first direction, extending from an upper surface of the second well region, and disposed in the second well region.

14. A power semiconductor device comprising:
a substrate including a first region and a second region surrounding the first region;
a drift layer of a first conductivity type on the substrate;
a first well region of a second conductivity type extending from an upper surface of the drift layer in the first region and further disposed within the drift layer;
a source region of the first conductivity type extending from an upper surface of the first well region and further disposed within the first well region;
an insulating liner on the drift layer;
an insulating pattern in the second region;
gate electrodes on the insulating liner in the first region and spaced apart from each other in a first direction with the source region interposed between the gate electrodes;
a conductive pattern spaced apart from the gate electrodes and covering a portion of the insulating liner and further covering a portion of the insulating pattern;
a dielectric layer covering the gate electrodes and further covering the conductive pattern; and
a source electrode on the dielectric layer in the first region,
wherein the conductive pattern includes a first pattern disposed on the insulating liner and a second pattern extending from the first pattern and disposed on the insulating pattern, and
the first pattern has a first height in a vertical direction intersecting the first direction from an upper surface of the insulating liner, and the second pattern has a second height, shorter than the first height, in the vertical direction, from an upper surface of the insulating pattern.

15. The power semiconductor device of claim 14, wherein upper surfaces of the gate electrodes are disposed on a same level as an upper surface of the conductive pattern.

16. The power semiconductor device of claim 14, wherein upper surfaces of the gate electrodes are disposed on a level higher than the upper surface of the insulating pattern.

17. The power semiconductor device of claim 14, wherein an upper surface of the first pattern is disposed on a same level as an upper surface of the second pattern.

18. The power semiconductor device of claim 14, wherein the conductive pattern includes a same material as the gate electrodes.

19. A power semiconductor device comprising:
a substrate of a first conductivity type;
a drift layer of the first conductivity type on the substrate;
a first well region of a second conductivity type on the drift layer;
a second well region of the second conductivity type disposed on the drift layer and spaced apart from the first well region in a first direction;
source regions of the first conductivity type on the first well region;
an insulating liner on the drift layer;
gate electrodes spaced apart from each other, with a source region of the source regions interposed between the gate electrodes, on the first well region;
an insulating pattern disposed on a portion of the insulating liner, on the second well region;
a conductive pattern spaced apart from the gate electrodes and covering a portion of the insulating liner and further covering a portion of the insulating pattern on the second well region;
a dielectric layer covering the gate electrodes and the conductive pattern;
a source electrode on the dielectric layer; and
a source contact plug penetrating through the dielectric layer and connecting the source electrode and the source region,
wherein the conductive pattern includes a first pattern in contact with the insulating liner and a second pattern in contact with the insulating pattern, and an upper surface of the first pattern and an upper surface of the second pattern are disposed on a same level, and
an upper surface of the dielectric layer is disposed on a same level as an upper surface of the source contact plug.

20. The power semiconductor device of claim 19, wherein the dielectric layer includes a side in contact with the source contact plug, an upper surface extending from the side, and a corner where the side and the upper surface are in contact.
